(19) United States
(12) Patent Application Publication
(10) Pub. No.: US 2005/0277034 A1
(43) Pub. Date: Dec. 15, 2005

(54) Mask blank, phase shift mask manufacturing method and template manufacturing method

(75) Inventor: Hideaki Mitsui, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION

(21) Appl. No.: 11/142,676

(22) Filed: Jun. 2, 2005

(30) Foreign Application Priority Data
Jun. 2, 2004 (JP) P2004-164956

(51) Int. Cl. B32B 9/00; B32B 17/06; G03C 5/00; G03F 1/00

(52) U.S. Cl. 430/5; 428/428; 430/322; 430/323; 430/324; 430/394

(57) ABSTRACT

A phase shift mask blank 10 having a very thin film (a chromium nitride film) 2 provided on a quartz substrate 1 for forming a phase shift pattern 1P and a resist film 3 formed thereon is used as a material, a resist pattern 3P is formed on the resist film 3, the very thin film 2 is etched by using the resist pattern as a mask, thereby forming a very thin film pattern 2P, the quartz substrate 1 is etched by using the very thin film pattern 2P as the mask, thereby forming the phase shift pattern 1P, and a light shielding film 4 is formed on the substrate 1 over which the formation of the phase shift pattern 1P and the removal of the resist pattern 3 are completed, and the light shielding film 4 is subjected to selective etching by using a resist 5, thereby exposing the phase shift pattern 1P while leaving a shielding portion 4A in a necessary part. Thus, a phase shift mask 20 is obtained. The thickness of the very thin film 2 is set to be a minimum thickness required for forming a phase shift pattern on the quartz substrate 1 by using the very thin film pattern 2P as the mask.

This application claims foreign priority based on Japanese Patent application No. 2004-164956, filed Jun. 2, 2004, the contents of which is incorporated herein by reference in its entirety.

### BACKGROUND OF THE INVENTION

1. Field of the Invention

The present invention relates to a mask blank for manufacturing a phase shift mask to be used in an ultra-resolution technique by applying a phase shift effect, and a method of manufacturing a phase shift mask using the mask blank, and furthermore, a mask blank for manufacturing a template to be a mother plate for a pattern transfer method by which a three-dimensional shape having a desirable fine pattern, such as represented by a nano-imprinting method, is transferred as it is, and a method of manufacturing a template itself.

2. Description of the Related Art

For example, some phase shift masks to be used in a phase shift method have the outer peripheral portions of transfer regions for a circuit pattern provided with a shielding band to prevent an exposed light from leaking out of the transfer region by an exposure which is carried out by means of a stepper or an alignment mark for an alignment such as disclosed in Japanese Patent No. 3282207. The shielding band and the alignment mark are generally formed by providing a light shielding film on a base layer such as a transparent substrate or a semitransparent film and carrying out pattern etching over the light shielding film.

Also in a template to be the mother plate of a pattern transfer method represented by a nano-imprinting method, moreover, the alignment mark is formed by the same method.

For the above reasons, a mask blank to be a material for manufacturing a phase shift mask or a template is offered in a product configuration in which a light shielding film is formed on a base layer such as a transparent substrate or a semitransparent film from a manufacturer for the mask blank to a user for fabricating a photomask or a template by using the mask blank.

The light shielding film for forming a shielding band or an alignment mark is also utilized as mask means for forming a three-dimensional pattern such as a phase shift pattern by etching a base layer such as a transparent substrate or a semitransparent film. In order to increase the resolution of the formation of a pattern, that is, to meet a demand for an enhancement in a fineness and an increase in precision of a circuit pattern, therefore, it can be supposed that a reduction in the thickness of a film to be carried out as greatly as possible is effective. In respect of the nature of the formation of the shielding band or the alignment mark, the performance of a shielding member, that is, a predetermined optical density (which is usually equal to or higher than 3), a reflectance or a film stress is required. For this reason, a reduction in the thickness of the film of the shielding member itself is limited. As a result, an enhancement in a resolution is limited.

### SUMMARY OF THE INVENTION

In consideration of the circumstances, it is an object of the invention to provide a mask blank which can contribute to an enhancement in a fineness and an increase in precision of a circuit pattern, and a method of manufacturing a phase shift mask or a template by using the mask blank.

In order to attain the object, a first aspect of the invention is directed to a mask blank to be used as a material when manufacturing a phase shift mask or a template, comprising at least a base layer, and a thin film wherein, said mask or template thereof is provided by the steps of forming the thin film on the base layer on which a three-dimensional pattern to be transferred is formed, forming a resist film on the thin film, forming a resist pattern by the resist film, and etching the thin film through the resist pattern functioning as a first mask, whereby a thin film pattern is formed, and etching the base layer through said thin film pattern functioning as a second mask, whereby the three-dimensional pattern is formed, further wherein a thickness of the thin film is set to be a minimum thickness required for forming the three-dimensional pattern on the base layer by using the thin film as the mask.

A second aspect of the invention is directed to the mask blank according to the first aspect of the invention, wherein the thickness of the very thin film is set to be 5 nm to 40 nm.

A third aspect of the invention is directed to a mask blank wherein a phase shift pattern is formed as a three-dimensional pattern for a transfer on a base layer and a light shielding film is then formed on the base layer from which the phase shift pattern is exposed.

A fourth aspect of the invention is directed to a method of manufacturing a phase shift mask by using the mask blank according to the first or second aspect of the invention as a material, comprising the steps of forming a thin film on a base layer on which a three-dimensional pattern to be transferred is formed; forming a resist layer on the thin film; forming a resist pattern by the resist layer of the mask blank; etching the thin film through the resist pattern functioning as a first mask, whereby a thin film pattern is formed; etching the base layer through the thin film pattern functioning as a second mask, whereby a phase shift pattern to be the three-dimensional pattern is etched on the base layer; removing the resist layer; forming a light shielding film on the base layer, and selectively etching the light shielding film by using a resist film with a pattern for a shielding portion being formed, whereby the phase shift pattern is exposed while leaving the shielding portion on a part of the base layer.

A fifth aspect of the invention is directed to the method of manufacturing a phase shift mask according to the fourth aspect of the invention, wherein the phase shift pattern is formed, and then, the very thin film pattern is once removed and the light shielding film is thereafter formed on the base layer from which the phase shift pattern is exposed, and the light shielding film is subjected to selective etching by using a resist, thereby exposing the phase shift pattern while leaving the shielding portion in the necessary place.

A sixth aspect of the invention is directed to the method of manufacturing a phase shift mask according to the fourth aspect of the invention, wherein the phase shift pattern is formed, and then, the very thin film pattern is not removed but left and the light shielding film is thereafter formed on the base layer from which the phase shift pattern is exposed, and the light shielding film and the very thin film are subjected to selective etching by using a resist, thereby exposing the phase shift pattern while leaving the shielding portion in the necessary place.

A seventh aspect of the invention is directed to the method of manufacturing a phase shift mask according to any of the fourth to sixth aspects of the invention, wherein the base layer is formed by a transparent substrate or by laminating a shift layer formed by a transparent or semitransparent film on the transparent substrate.

An eighth aspect of the invention is directed to the method of manufacturing a phase shift mask according to any of the fourth to seventh aspects of the invention, wherein a dry etching selective ratio in etching of a base layer for forming the phase shift pattern in a material constituting the very thin film and a material constituting the base layer satisfies a relational expression:
(etching rate of base layer)/(etching rate of very thin film)≧5.
In this case, it is preferable that dry etching using a gas containing a fluorine gas should be carried out.

A ninth aspect of the invention is directed to the method of manufacturing a phase shift mask according to any of the fourth to eighth aspects of the invention, wherein the very thin film is formed by a material containing at least Cr and/or Ta.

A tenth aspect of the invention is directed to the method of manufacturing a phase shift mask according to any of the fourth to ninth aspects of the invention, wherein the selective etching for the light shielding film which is to be carried out is of a wet type.

An eleventh aspect of the invention is directed to the method of manufacturing a phase shift mask according to any of the fourth to ninth aspects of the invention, wherein the selective etching for the light shielding film which is to be carried out is of a dry type. In this case, it is preferable that dry etching using a gas containing chlorine should be carried out.

A twelfth aspect of the invention is directed to a method of manufacturing a template to be a mother plate of a pattern transfer method such as nano-imprinting by using the mask blank according to the first or second aspect of the invention as a material, comprising the steps of forming a thin film on a base layer on which a three-dimensional pattern to be transferred is formed; forming a resist layer on the thin film; forming a resist pattern by the resist layer of the mask blank; etching the thin film through the resist pattern functioning as a first mask, whereby a thin film pattern is formed; etching the base layer through the thin film pattern functioning as a second mask, whereby the three-dimensional pattern is etched on the base layer; removing the resist layer; forming an alignment mark forming film on the base layer, and selectively etching the alignment mark forming film by using a resist film with a pattern for an alignment mark portion being formed, whereby the phase shift pattern is exposed while leaving a desirable alignment mark in any part of outer peripheral portion other than a portion of the three-dimensional pattern being formed.

The mask blank according to the first aspect of the invention sets the thickness of a very thin film laminated on the base layer to fulfill a mask function in the etching of the base layer to be a minimum thickness required for forming a pattern by the etching and specializes the role of the very thin film in processing mask means for forming a pattern, that is, eliminates a limitation for maintaining an optical density and specializes the very thin film in the role of the processing mask means. Therefore, it is possible to contribute to an enhancement in a fineness and an increase in precision of a three-dimensional pattern to be formed on the base layer. In that case, it is desirable that the thickness of the very thin film should be set to be 5 nm to 40 nm as in the second aspect of the invention.

The mask blank according to the third aspect of the invention has such a structure that the phase shift pattern is formed on the base layer and the light shielding film is then formed newly on the base layer. Therefore, it is possible to manufacture a phase shift mask by selectively etching the light shielding film and exposing the phase shift pattern while leaving the shielding portion in a necessary place.

According to the method of manufacturing a phase shift mask in accordance with the fourth aspect of the invention, the phase shift pattern is formed on the base layer by using the very thin film pattern as a mask, and then, the light shielding film is newly formed on the base layer and is subjected to the selective etching. Consequently, the phase shift pattern is exposed with the shielding portion left in a necessary place, and the very thin film to be utilized as the mask means in the formation of the phase shift pattern and the light shielding film for forming the shielding portion are provided completely separately from each other. Therefore, the thickness of a first very thin film can be specialized in an enhancement in the resolution of the pattern formation and can be thus determined. By setting the thickness of the film to be a minimum thickness required for the pattern formation, it is possible to contribute to the enhancement in the resolution.

According to the method of manufacturing a phase shift mask in accordance with the fifth aspect of the invention, the very thin film pattern used as the mask means is once removed after the formation of the phase shift pattern and the light shielding film is newly formed. Also in the case in which the etching conditions of the very thin film and the light shielding film are different from each other, therefore, they can be processed on the independent etching conditions respectively. Thus, it is possible to easily manage the etching.

According to the method of manufacturing a phase shift mask in accordance with the sixth aspect of the invention, the very thin film pattern used as the mask means is not removed but left after the formation of the phase shift pattern and the light shielding film is newly formed, and then, the light shielding film and the very thin film are subjected to selective etching by using the resist. Therefore, it is possible to carry out a material design and a process design from which a step of removing the very thin film pattern is omitted.

According to the method of manufacturing a phase shift mask in accordance with the seventh aspect of the invention, in the case in which the base layer is formed by only the transparent substrate and the case in which the base layer is obtained by laminating the shift layer formed by a transparent film on the transparent substrate, a transmission type phase shift mask can be fabricated. In the case in which the shift layer formed by the semitransparent film is laminated on the transparent substrate, a halftone type phase shift mask can be fabricated.

According to the method of manufacturing a phase shift mask in accordance with the eighth aspect of the invention, the dry etching selective ratio of the material of the very thin film to the material of the base layer is limited. Consequently, it is possible to define the thickness of the very thin film to be a minimum on the basis of the dry etching rate of the base layer.

According to the method of manufacturing a phase shift mask in accordance with the ninth aspect of the invention, the very thin film is formed by a material containing at least Cr and/or Ta. Therefore, it is possible to easily carry out an application to an existing photomask process.

According to the method of manufacturing a phase shift mask in accordance with the tenth aspect of the invention, the selective etching for the light shielding film is of the wet type which rarely damages the base layer. Consequently, it is possible to apply a mask process having a small process load.

According to the method of manufacturing a phase shift mask in accordance with the eleventh aspect of the invention, the selective etching for the light shielding film is of the dry type. Consequently, it is possible to design a suitable and flexible mask process while implementing a high precision mask processing.

According to the method of manufacturing a template in accordance with the twelfth aspect of the invention, the three-dimensional pattern is formed on the base layer by using the very thin film pattern as a mask, and then, the light shielding film is newly formed on the base layer and is subjected to the selective etching. Consequently, the three-dimensional pattern is exposed with the shielding portion left in a necessary place, and the very thin film to be utilized as the mask means in the formation of the three-dimensional pattern and the light shielding film for forming the alignment mark are provided completely separately from each other. Therefore, the thickness of a first very thin film can be specialized in an enhancement in the resolution of the pattern formation and can be thus determined. By setting the thickness of the film to be a minimum thickness required for the pattern formation, it is possible to contribute to the enhancement in the resolution.

### BRIEF DESCRIPTION OF THE DRAWINGS

FIGS. 1(a) to 1(j) are the views showing a process according to an embodiment 1 of the invention,

FIGS. 2(a) to 2(j) are the views showing a process according to an embodiment 2 of the invention,

FIGS. 3(a) to 3(j) are the views showing a process according to an embodiment 3 of the invention,

FIGS. 4(a) to 4(j) are the views showing a process according to an embodiment 4 of the invention,

FIGS. 5(a) to 5(j) are the views showing a process according to an embodiment 5 of the invention, and

FIGS. 6(a) to 6(j) are the views showing a process according to an embodiment 6 of the invention.

### DESCRIPTION OF THE PREFERRED EMBODIMENTS

Embodiments of the present invention will be described hereinbelow by reference to the drawings. Unless otherwise specifically defined in the specification, terms have their ordinary meaning as would be understood by those of ordinary skill in the art.

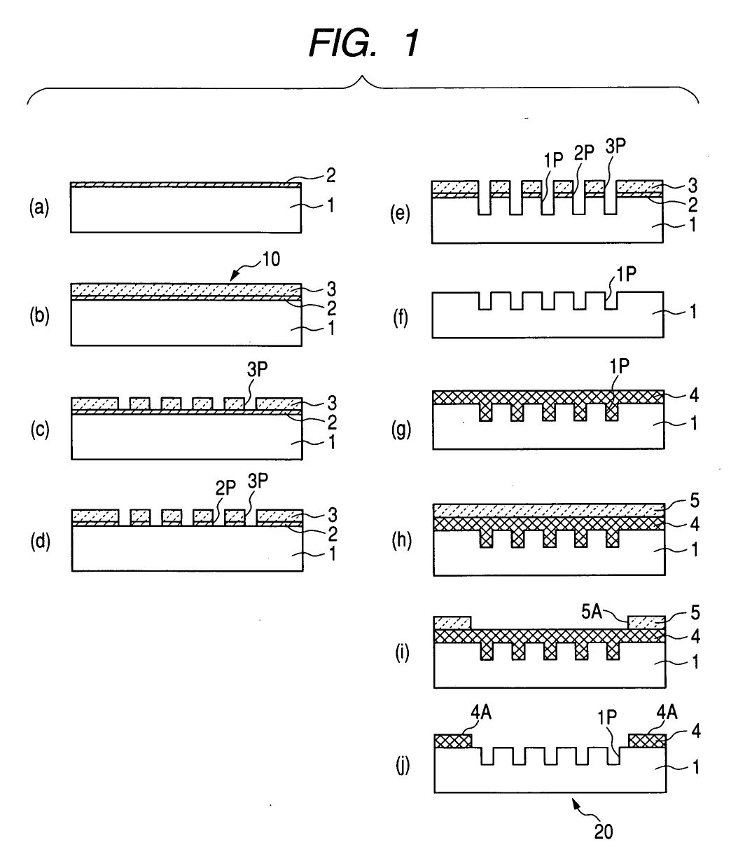

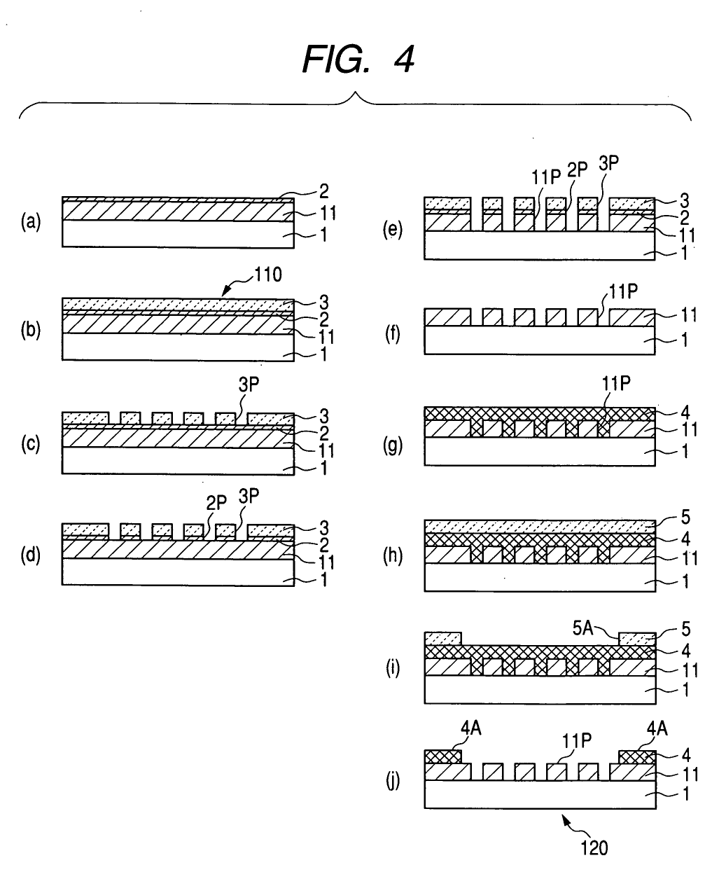

As an embodiment of the layer structure of a first mask blank, a transparent substrate 1 such as quartz is set to be abase layer and a very thin film 2 and a resist film 3 are sequentially formed thereon as shown in FIG. 1(b). As an embodiment of the layer structure of a second mask blank, moreover, a shift layer formed by a transparent film is provided on the transparent substrate to constitute the base layer, and the very thin film and the resist film are sequentially formed thereon. As an embodiment of the layer structure of a third mask blank, furthermore, a halftone layer (a shift layer) 11 formed by a semitransparent film is provided on the transparent substrate 1 to constitute the base layer, and the very thin film 2 and the resist film 3 are sequentially formed thereon as shown in FIG. 4(b).

For both of mask blanks 10 and 110, the thickness of the very thin film 2 is set to be a minimum thickness required for forming the three-dimensional pattern of a phase shift mask on a base layer (a transparent substrate or the transparent substrate on which a shift layer is provided) by using, as a mask, a pattern formed on the very thin film 2, for embodiment, a range of 5 nm to 40 nm. Moreover, the very thin film 2 is constituted by a material containing at least Cr and/or Ta. Furthermore, a dry etching selective ratio in the etching of a base layer of a material constituting the very thin film 2 to a material constituting the base layer is set to satisfy the following relational expression:
(etching rate of base layer)/(etching rate of very thin film)≧5.

As shown in an embodiment of FIG. 1, a manufacturing method according to an embodiment in which a phase shift mask is manufactured by using the mask blank as a material comprises (c) a step of forming a resist pattern 3P on the resist film 3 of the mask blank 10, (d) a step of etching the very thin film 2 by using the resist pattern 3P as a mask, thereby forming a very thin film pattern 2P, (e) a step of etching the base layer (the transparent substrate 1) by using the very thin film pattern 3P as a mask, thereby forming a phase shift pattern 1P to be a three-dimensional pattern, (g) forming a light shielding film 4 on the base layer (the transparent substrate 1) in which the formation of the phase shift pattern 1P and at least the removal of the resist layer 3 are completed, and (h) to (j) a step of selectively etching the light shielding film 4 by using a resist 5, thereby exposing the phase shift pattern 1P while leaving a shielding portion 4A in a necessary part.

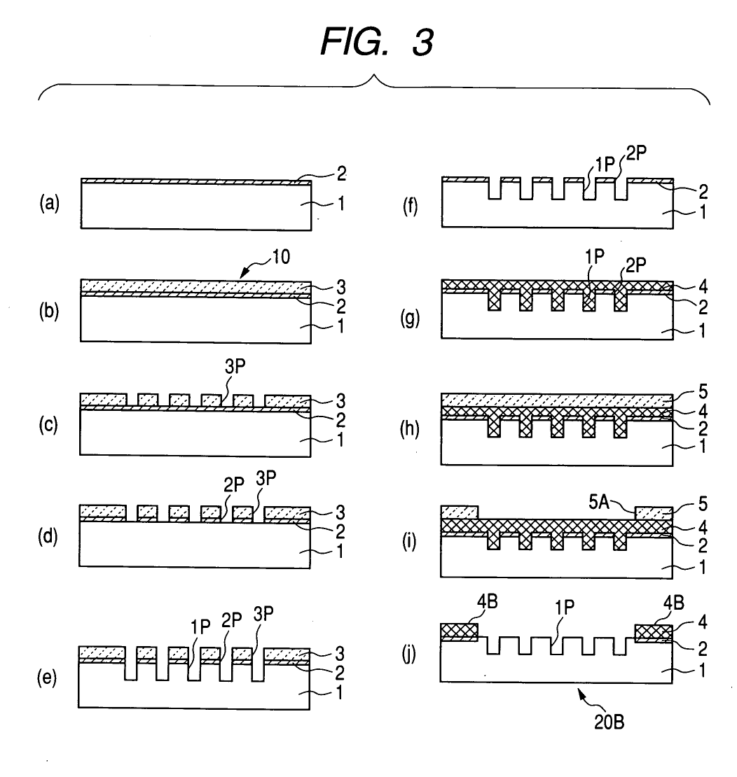

In this case, there are a method of forming the phase shift pattern 1P and then removing the very thin film pattern 2P once (f), forming the light shielding film 4 on the base layer (the transparent substrate 1) from which the phase shift pattern 1P is exposed and selectively etching the light shielding film 4 by using the resist 5, thereby exposing the phase shift pattern 1P while leaving the shielding portion 4A in a necessary part as shown in FIG. 1 and a method of forming the phase shift pattern 1P and then forming the light shielding film 4 on the base layer (the transparent substrate 1) from which the phase shift pattern 1P is exposed while leaving the very thin film pattern 2P, and selectively etching the light shielding film 4 and the very thin film 2 by using the resist 5, thereby exposing the phase shift pattern 1P while leaving a shielding portion 4B in a necessary part as shown in FIG. 3. The selective etching for the light shielding film 4 may be of a wet type or a dry type.

While the above description has been given to the case in which the phase shift mask is manufactured, moreover, it is also possible to manufacture a template to be used in a nanoimprinting method by the mask blank.

In that case, a manufacturing method executes, in order, a step of forming a resist pattern on the resist film of a mask blank, a step of etching a very thin film by using the resist pattern as a mask to form a very thin film pattern, a step of etching a base layer by using the very thin film pattern as the mask to form a three-dimensional pattern, a step of forming an alignment mark forming film on a base layer over which the formation of a phase shift pattern and at least the removal of the resist layer are completed, and a step of selectively etching the alignment mark forming film by using a resist, thereby exposing a three-dimensional pattern while leaving a desirable alignment mark in any of outer peripheral portions other than a portion in which the three-dimensional pattern is formed.

Next, a specific embodiment will be described. Embodiments 1 to 3 show the steps of a method of fabricating a transmission type phase shift mask and embodiments 4 to 6 show the steps of a method of fabricating a halftone type phase shift mask.

### Embodiment 1

A method of manufacturing a phase shift mask according to an embodiment 1 will be described with reference to FIG. 1.

First of all, a chromium nitride film (a very thin film) 2 was formed in a thickness of 5 nm on a transparent substrate (hereinafter referred to as a quartz substrate) 1 by using a sputtering method, and the quartz substrate 1 having the very thin chromium nitride film 2 for a processing shown in (a) was fabricated. The chromium nitride film 2 was fabricated in a reactive sputtering film formation using chromium as a sputter target and a nitrogen gas as a sputter gas. The thickness of the very thin chromium nitride film 2 was measured by an optical film thickness meter. Referring to the accuracy of a measured value, moreover, the substrate 1 and the chromium nitride film 2 were broken to observe and confirm a sectional TEM (a tunnel electron microscope) image.

Next, an electron beam resist film 3 (manufactured by Fuji Film Arch (FFA) Co., Ltd.: Trade number CAR-FEP171) was applied onto the quartz substrate 1 having the very thin chromium nitride film 2 for a processing so that a mask blank 10 shown in (b) was obtained.

As shown in (c), then, electron beam drawing based on a desirable pattern was carried out. Thereafter, the resist 3 was developed to form a resist pattern (primary pattern) 3P. Subsequently, the very thin chromium nitride film 2 for a processing was subjected to dry etching along the resist pattern 3P by using a mixed gas of chlorine and oxygen (a mixed gas of Cl₂:O₂=90 sccm:10 sccm) in the same manner as in a normal photomask processing. Consequently, a chromium nitride film pattern 2P (secondary pattern) shown in (d) was obtained.

In this case, a time required for the etching was approximately 13 seconds on a standard dry etching condition (the etching gas mixing ratio described above, a gas pressure: 10 mTorr and an RF output; 500 W), and the etching was ended in 20 seconds including a time required for over-etching. The etching time was sufficiently shorter as compared with the case in which a normal time required for etching a light shielding film for a photomask is approximately seven minutes (the thickness of a normal Cr light shielding film: 1050 Å), and the etching damages (backward movement and deformation) of the resist pattern 3P could also be suppressed more greatly as compared with a reduction in the etching time.

As shown in (e), next, the quartz substrate 1 was etched in a predetermined amount through dry etching using a gas containing fluorine by setting the very thin chromium nitride pattern 2P as an etching mask for a next step while leaving the resist pattern 3P. Thus, a phase shift pattern 1P (tertiary pattern) was obtained. In the embodiment, the etching was carried out for 8 minutes and 30 seconds at an etching pressure of 5 mTorr and an RF output of 200 W by using a mixed gas of CHF₃ and O₂ for an etching gas (CHF₃:O₂=95 sccm:5 sccm).

The amount of etching dig of the quartz substrate 1 according to the embodiment was regulated in such a manner that an optical phase difference is 180 degrees in the phase shift pattern 1P portion with a light having a wavelength of 193 nm. In this case, the very thin chromium nitride film pattern 2P to be the basis of a transfer pattern sufficiently functioned as an etching mask during the etching of the quartz substrate 1.

As shown in (f), then, the resist pattern 3P was removed by predetermined acid cleaning. Thereafter, the chromium nitride film pattern 2P was removed with a cerium ammonium nitrate solution so that a processed substrate having a desirable quartz digging pattern was obtained.

As shown in (g), subsequently, a light shielding film 4 formed by a material containing Cr was provided on the pattern processed quartz substrate 1 obtained at the previous step by using a sputtering method. For the light shielding film 4 formed by the material containing Cr, an optical density, a reflectance and a film stress which are generally used in a light shielding film for a photomask were employed. The thickness of the light shielding film 4 according to the embodiment was approximately 105 nm.

As shown in (h), next, a positive photoresist was applied onto the light shielding film 4 to form a resist film 5, and exposure and wet developing were then carried out if necessary. In the embodiment, the pattern (shielding portion) of a shielding band 4A was formed by opening the central portion of a photomask (an opening portion 5A) as shown in (i) to expose the main pattern portion of the photomask by using THMR iP-3500 (manufactured by TOKYO OHKA CO., LTD.) for the photoresist.

Furthermore, the light shielding film 5 portion exposed to the resist pattern opening portion 5A was removed by wet etching using the cerium ammonium nitrate solution based on a photoresist pattern thus obtained.

By the above steps, it was possible to obtain a photomask 20 (a phase shift mask) including the shielding band 4A in an outer peripheral portion thereof and having a main pattern constituted by a quartz pattern.

In the manufacturing method, the very thin chromium nitride film pattern 2P (the secondary pattern) to be a transfer source in the formation of the main pattern of the photomask (the phase shift pattern 1P=tertiary pattern) has a thickness reduced by narrowing main points down to the transfer processing of the resist pattern 3P (the primary pattern). Therefore, it is possible to form the secondary pattern on an etching condition that a time required for etching is sufficiently shorter and a sufficiently smaller damage is caused as compared with a pattern forming method which has conventionally been carried out. As a result, it was possible to obtain a closer transfer pattern to the primary pattern.

### Embodiment 2

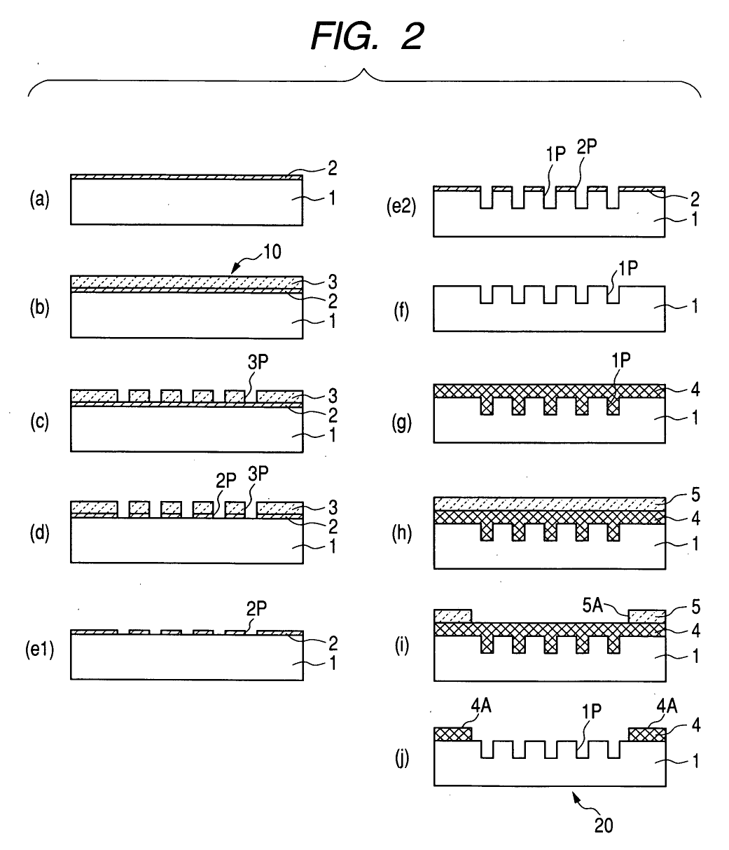

An embodiment 2 will be described with reference to FIG. 2. The embodiment 2 shows the case in which a resist pattern 3P to be a primary pattern is removed.

In the embodiment, the thickness of a chromium nitride film 2 to be formed on a quartz substrate 1 was first set to be 40 nm. Other portions were the same as those in the Embodiment 1. The thickness of the chromium nitride film 2 was different from that in the embodiment 1. In embodiment, however, the chromium nitride film 2 was processed by etching for 120 seconds including an over-etching time (a just etching time: 100 seconds) on the same chromium nitride dry etching condition as that in the embodiment 1. Also in this case, in the same manner as in the embodiment 1, the processing can be carried out in a sufficiently shorter time than a normal time required for etching a light shielding film containing chromium.

The same processings as in the embodiment 1 were carried out from (a) to (d). After the end of the step (d) (a step of forming a chromium nitride film pattern 2P), the resist pattern 3P (the primary pattern) was removed (e1) by a predetermined resist removing method and cleaning method. In this case, it is preferable to employ, for the removal of a resist, a method of preventing a very thin chromium nitride film pattern 2P (a secondary pattern) and a quartz substrate 1 material from being damaged in consideration of the fidelity of a pattern transfer.

In the embodiment, a resist remover specified for the resist was used to carry out predetermined cleaning. Consequently, the resist pattern 3P was substantially removed. After the removal of the resist pattern, the quartz substrate 1 to be a ground was processed through dry etching by setting, as a mask, the very thin chromium nitride film pattern 2P which was exposed (the secondary pattern) (e2) in the same manner as in the embodiment 1. Subsequent steps (f) to (j) are the same as those in the embodiment 1. At the step (f), the resist pattern 3P has already been removed in this stage. Therefore, the very thin chromium nitride film pattern 2P which was left was subjected to wet removal in the same manner as in the embodiment 1.

Advantages produced in the case in which the resist pattern 3P is thus removed and the ground base material (the quartz substrate 1) is then subjected to dry etching include an enhancement in processing quality obtained by the prevention of an organic contamination in a dry etching device (the readhesion of an organic matter) and a defect caused by a resist and the avoidance of a chemical active species imbalance on a dry etching surface because a resist constituted by an organic matter is removed at time of dry etching. In the dry etching, the same conditions as those in the embodiment 1 were used.

During the etching of the quartz substrate 1 carried out with a mixed gas of CHF₃ and oxygen, the dry etching selective ratio of SiO₂ constituting quartz to the chromium nitride film was approximately 20 to 1, and the disappearance of the chromium nitride film by an ion damage was caused in a thickness of approximately 8.5 nm. In the embodiment, accordingly, the pattern 2P obtained by the chromium nitride film fully functioned as an etching mask in the patterning of the quartz.

In some cases in which the resist pattern 3P is removed and the ground is then processed with a fluorine type gas by using the very thin chromium nitride film pattern 2P as in the embodiment, the topmost surface of the chromium nitride film is fluorinated if the etching condition is severe, for embodiment, an etching output is high. When the topmost surface is considerably fluorinated, there is a possibility that a very thin chromium type film might not be removed uniformly at a subsequent wet step. For this reason, it is necessary to pay attention to the etching condition based on the fluorine type gas. A method of taking countermeasures against such a case will be described in Embodiment 3.

### Embodiment 3

A third embodiment will be described with reference to FIG. 3.

A chromium nitride film 2 was used for a very thin film in the same manner as in the embodiment 1. The thickness of the chromium nitride film 2 was set to be 5 nm in the same manner as in the embodiment 1. Steps (a) to (e) were the same manner as those in the embodiment 1. At the step (e), the dry etching processing of a quartz substrate 1 was ended and only a resist pattern 3P (a primary pattern) was then removed. In a state in which a very thin chromium nitride pattern 2P (a secondary pattern) was left as shown in (f), a normal light shielding film 4 was formed as shown in (g). Consequently, a step of removing the very thin chromium nitride film 2 can be omitted so that a great advantage can be obtained in the process.

Also in the embodiment, subsequently, selective etching using a resist 5 was carried out as shown in steps (h) to (j) in the same manner as in the embodiments 1 and 2. Consequently, a photomask 20B including the pattern of a shielding band 4B was obtained.

Another advantage produced by the employment of the manufacturing method is as follows. By properly selecting the material of the very thin film 2 for forming the secondary pattern, it is possible to use a different material from the material of a conventional light shielding film containing chromium. In the final photomask 20B, consequently, it is possible to interpose an optional thin film between the substrate 1 and the material of the conventional light shielding film 4.

As an embodiment, a chromium oxide film having a smaller exhaustion coefficient and a smaller refractive index than those of chromium nitride in a desirable optical wavelength is applied to the very thin film 2 and is interposed between the conventional light shielding film 4 and the substrate 1. Consequently, it is possible to suitably control the influence of an optical reflection on an interface between the light shielding film 4 and the substrate 1.

### Embodiment 4

An embodiment 4 will be described with reference to FIG. 4.

In the embodiment, a halftone phase shift film for ArF (a shift layer formed of a semitransparent film) 11 constituted by MoSiN (molybdenum silicide nitride) is provided on a quartz substrate 1 and a very thin chromium nitride film 2 is provided thereon as shown in (a). The MoSiN film 11 is designed as a halftone type phase shift film for ArF and has a transmittance of 6% in a thickness (approximately 69 nm) for the inversion of the phase of an exposed light by 180 degrees with an ArF wavelength.

In the embodiment, the very thin chromium nitride film 2 having a thickness of 5 nm was formed on the MoSiN film 11 and a resist film 3 was formed thereon so that a mask blank 110 shown in (b) was obtained in the same manner as in the embodiment 1.

At steps (c) to (f), the same resist process and patterning process as that in the embodiment 1 was carried out over the mask blank 110, and the very thin chromium nitride film 2 was etched by using a resist pattern 3P and the MoSiN film 11 was then etched by using a very thin chromium nitride film pattern 2P with the resist pattern 3P left, and a pattern (a tertiary pattern) was thus transferred. The etching was executed by using a mixed gas of CF₄ and oxygen (CF₄:O₂=95 sccm:5 sccm) at a gas pressure of 5 mTorr and an RF output of 200 W. Consequently, a desirable halftone mask pattern (tertiary pattern) 11P was formed on the MoSiN film 11.

At steps (f) to (j), thereafter, the resist pattern 3P and the chromium nitride film pattern 2P were removed, and a normal light shielding film 4 containing chromium was then formed on a surface from which the halftone mask pattern 11P formed of MoSiN was exposed, and furthermore, a photoresist was applied, exposed and developed so that a shielding band 4A based on the light shielding film 4 and a desirable pattern were formed, and subsequently, a halftone type phase shift mask (a phase shift mask) 120 having a main pattern portion exposed was obtained in the same manner as in the embodiment 1.

Also in the manufacturing method, in the same manner as in the embodiment 1, the very thin chromium nitride film pattern 2P (the secondary pattern) to be a transfer source in the formation of the main pattern of the photomask (the halftone mask pattern 11P=tertiary pattern) has a thickness reduced by narrowing main points down to the transfer processing of the resist pattern 3P (the primary pattern). Therefore, it is possible to form the secondary pattern on an etching condition that a time required for etching is sufficiently shorter and a sufficiently smaller damage is caused as compared with a pattern forming method which has conventionally been carried out. As a result, it is possible to obtain a closer transfer pattern to the primary pattern.

### Embodiment 5

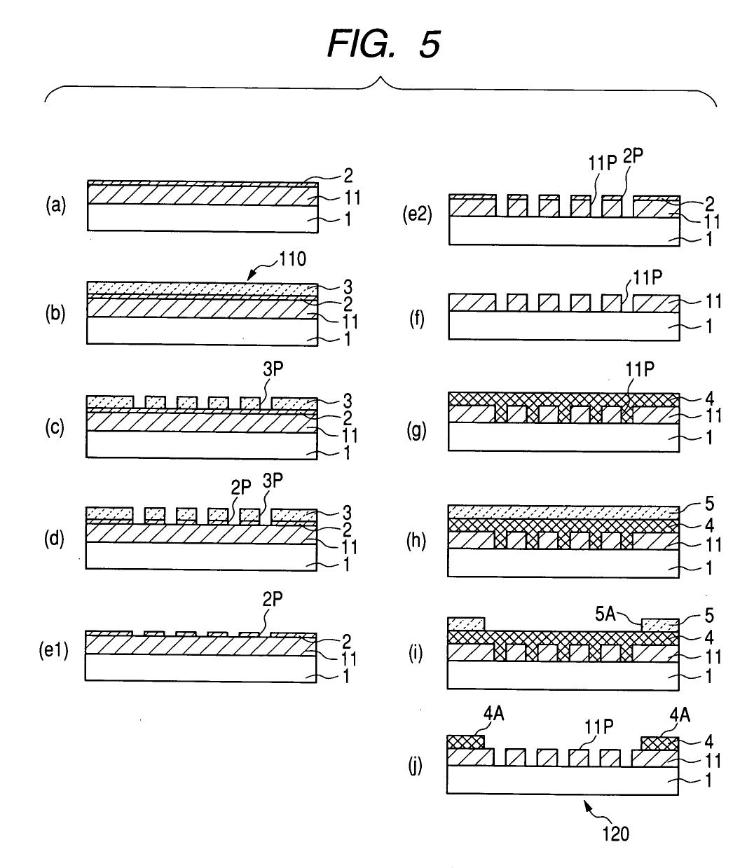

FIG. 5 shows steps in an embodiment 5. The embodiment 5 shows the case in which the same steps as those in the embodiment 2 are carried out over a mask blank 110 having a halftone type phase shift film 11 formed on a quartz substrate 1 as shown in the embodiment 4 so that a halftone type phase shift mask 120 was manufactured.

### Embodiment 6

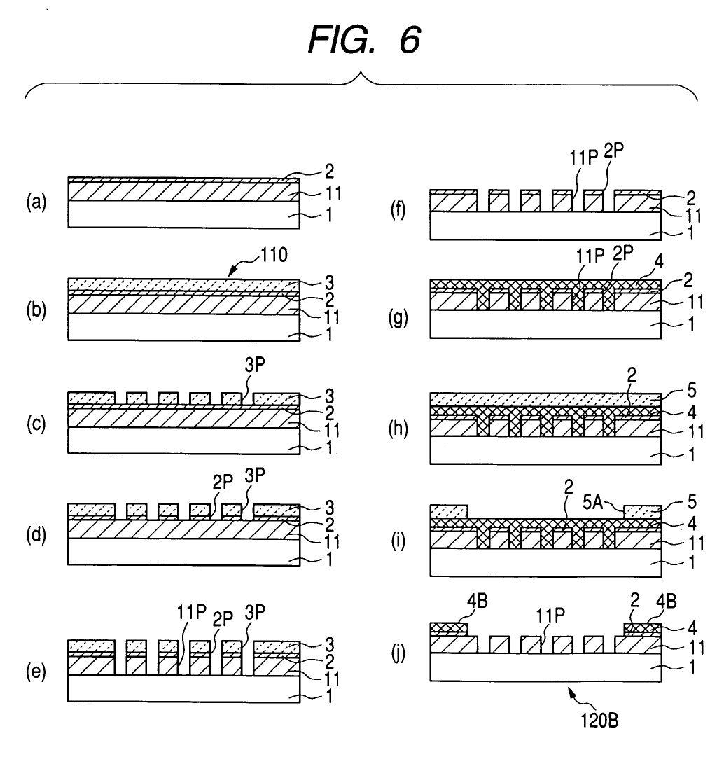

FIG. 6 shows steps in an embodiment 6. The embodiment 6 shows the case in which the same steps as those in the embodiment 3 are carried out over a mask blank 110 having a halftone type phase shift film 11 formed on a quartz substrate 1 as shown in the embodiment 4 so that a halftone type phase shift mask 120B was manufactured.

### Embodiment 7

An embodiment 7 shows the case in which a template for a nanoimprinting method having an alignment mark is fabricated differently from the phase shift mask described above. In this case, first of all, the same steps as (a) to (g) in the embodiment 1 were executed so that a desirable light shielding film 4 containing chromium was given onto a processed mask obtained by processing a desirable three-dimensional pattern over a quartz substrate 1. The depth of the three-dimensional pattern formed on the quartz substrate 1 was set to be a depth required for the nanoimprinting method which is intended.

After a photoresist was applied thereto, a light was exposed to the photoresist in such a manner that a desirable alignment mark was formed in any of outer peripheral portions other than a portion on the quartz substrate 1 in which the three-dimensional pattern was formed, and the resist was developed and the unnecessary light shielding film 4 was removed so that a template mask for the nanoimprinting method having the alignment mark was fabricated.

Also in the template manufacturing method, a very thin chromium nitride film pattern 2P (a secondary pattern) to be a transfer source in the formation of a main pattern (a tertiary pattern) has a thickness reduced by narrowing main points down to the transfer processing of a resist pattern 3P (a primary pattern). Therefore, it is possible to form the secondary pattern on an etching condition that a time required for etching is sufficiently shorter and a sufficiently smaller damage is caused as compared with a pattern forming method which has conventionally been carried out. As a result, it is possible to obtain a closer transfer pattern to the primary pattern.

Referring to the very thin film 2 used in these embodiments, it is desirable to chemically distinguish the very thin film 2 from other layers or substrate materials in consideration of the working process of a mask. The material containing chromium represented by the chromium nitride used in the embodiment can easily be distinguished from other materials containing silicon, particularly, in both a wet process and a dry (dry etching) process, and is suitable for the object.

In addition to the material containing chromium, particularly, it is possible to take, as an embodiment, a material containing tantalum (Ta), zirconium, hafnium or tungsten which can be distinguished from a material containing silicon in the dry (dry etching) process (an alloy, oxides, nitrides, carbides, oxynitrides, carbonitrides and oxy- and nitrocarbides of a single metal, and similarly, oxides, nitrides, carbides, oxynitrides, carbonitrides and oxy-nitrocarbides of the alloy).

Even if a base material to be processed finally is a material containing quartz or silicon, moreover, it is possible to make a difference in a processing speed between the very thin film 2 and a final processing material by selecting gas species for etching in a dry working process which will be described below. By utilizing the difference, it is possible to suitably use a material containing silicon.

As an embodiment, in dry etching using a gas containing SF₆ in an etching gas, an etching rate difference which is almost 20 times as much is made between Si and SiO₂.

For a film composition in the direction of the thickness of the very thin film 2 to be fabricated by using the material, moreover, a multilayer film may be utilized or an inclined composition may be provided in the direction of the thickness of a film in order to give optical, chemical and physical functions to the film itself. As an embodiment, in case of the optical function, it is possible to carry out a design in such a manner that an oxide film or an oxynitride film is positioned on the surface layer of the film in order to control a reflectance for a desirable wavelength in a quality check for a thin film which is to be performed after the fabrication of the very thin film.

If the main function of a very thin film for a processing is not obstructed, similarly, it is possible to optionally design a composition in the vicinity of the surface layer of the film in order to enhance a chemical durability.

Referring to a physical characteristic, moreover, oxygen, nitrogen, carbon or hydrogen is introduced into the film or a plurality of films having different film stresses is laminated in order to relieve the film stress of the whole very thin film, for embodiment. Thus, it is also possible to control the stress by using a bimetal effect.

On the other hand, various dry etching gases used in the embodiments are not restricted to the foregoing. In case of a chlorine type gas, for embodiment, Cl₂, SiCl₄, CHCl₃ and CCl₄ can be employed.

Referring to a fluorine type gas, similarly, it is possible to use SF₆ and C₄F₈ depending on the process in addition to CF₄ and CHF₃. For these etching gases, it is also possible to use other halogen type gases containing bromine or iodine.

As an embodiment of the invention, moreover, it is possible to minimize the thickness of the very thin film 2 provided under the resist forming the primary pattern. As a result, it is possible to further decrease the thickness of the resist film 3 forming the primary pattern.

For embodiment, it is effective that the thickness of the film of the resist is decreased in order to reduce the aspect ratio (a pattern depth/a pattern width) of a resist pattern to suppress a microloading phenomenon which becomes a problem in the dry etching of a phase shift film or a quartz substrate. Similarly, it is effective that the aspect ratio is reduced against the collapse of a resist pattern with the microfabrication of the pattern. By the execution of the invention, a load to be applied to a resist function is substantially reduced. Consequently, it is possible to suitably deal with the problems described above.

In a photomask, moreover, a reticle alignment mark for setting a photomask (reticle) to an exposing machine and a mark for an alignment (a wafer alignment mark) to superpose die plates on a wafer to carry out an exposure are generally provided on the outside of a main pattern area. These alignment marks are not formed by a shielding pattern as usual but can also be formed by a pattern obtained by digging a quartz substrate to be a transparent material. In the case in which a light semitransmitting film is used, alternatively, it is also possible to form a pattern on the light semitransmitting film in the same manner as a main pattern and to use the pattern as various alignment marks. In other words, it is possible to recognize a pattern having a high transmittance or a light semitransmitting pattern by utilizing a phase inversion at a pattern edge.

Alternatively, a desirable alignment mark is formed in the same manner as in the very thin film pattern 2P and only an alignment mark portion is selectively protected by a resist, and similarly, the formation of a light shielding film at a subsequent step is not partially carried out. Consequently, it is also possible to form the alignment mark of the very thin film. Any of the alignment marks which is suitable can be selected depending on the modes of a photomask and a photomask process which are used.

Moreover, the manufacturer of a mask blank can also offer, to a user side, a mask blank obtained by forming a phase shift pattern as a three-dimensional pattern for a transfer on a base layer and then forming a light shielding film on the base layer from which the phase shift pattern is exposed, which has not been described above.

It will be apparent to those skilled in the art that various modifications and variations can be made to the described preferred embodiments of the present invention without departing from the spirit or scope of the invention. Thus, it is intended that the present invention cover all modifications and variations of this invention consistent with the scope of the appended claims and their equivalents.

1. A mask blank to be used for manufacturing a phase shift mask or a template, comprising at least a base layer, and a thin film wherein,
said mask or the template is provided by the steps of forming the thin film on the base layer on which a three-dimensional pattern to be transferred is formed, forming a resist film on the thin film, forming a resist pattern by the resist film, and etching the thin film through the resist pattern functioning as a first mask, whereby a thin film pattern is formed, and etching the base layer through said thin film pattern functioning as a second mask, whereby the three-dimensional pattern is formed, further wherein
a thickness of the thin film is set to be a minimum thickness required for forming the three-dimensional pattern on the base layer by using the thin film as the mask.

2. The mask blank according to claim 1, wherein the thickness of the very thin film is set to be 5 nm to 40 nm.

3. The mask blank according to claim 1, wherein a phase shift pattern is formed as a three-dimensional pattern for a transfer on a base layer and a light shielding film is then formed on the base layer from which the phase shift pattern is exposed.

4. A method of manufacturing a phase shift mask by using a mask blank, comprising the steps of:
forming a thin film on a base layer on which a three-dimensional pattern to be transferred is formed;
forming a resist layer on the thin film;
forming a resist pattern by the resist layer of the mask blank;
etching the thin film through the resist pattern functioning as a first mask, whereby a thin film pattern is formed;
etching the base layer through the thin film pattern functioning as a second mask, whereby a phase shift pattern to be the three-dimensional pattern is etched on the base layer;
removing the resist layer;
forming a light shielding film on the base layer, and
selectively etching the light shielding film by using a resist film with a pattern for a shielding portion being formed, whereby the phase shift pattern is exposed while leaving the shielding portion on a part of the base layer.

5. The method of manufacturing a phase shift mask according to claim 4, wherein the thin film pattern is removed after removing the resist layer, but prior to forming said light shielding film on the base layer light shielding film light shielding film.

6. The method of manufacturing a phase shift mask according to claim 4, wherein the phase shift pattern is formed, and then, the very thin film pattern is not removed but left and the light shielding film is thereafter formed on the base layer from which the phase shift pattern is exposed, and the light shielding film and the very thin film are subjected to selective etching by using a resist, thereby exposing the phase shift pattern while leaving the shielding portion in the necessary place.

7. The method of manufacturing a phase shift mask according to claim 4, wherein the base layer is formed by a transparent substrate or by laminating a shift layer formed by a transparent or semitransparent film on the transparent substrate.

8. The method of manufacturing a phase shift mask according to claim 4, wherein a dry etching selective ratio in etching of a base layer for forming the phase shift pattern in a material constituting the very thin film and a material constituting the base layer satisfies a relational expression:
(etching rate of base layer)/(etching rate of very thin film)≧5.

9. The method of manufacturing a phase shift mask according to claim 4, wherein the very thin film is formed by a material containing at least Cr and/or Ta.

10. The method of manufacturing a phase shift mask according to claim 4, wherein the selective etching for the light shielding film which is to be carried out is of a wet type.

11. The method of manufacturing a phase shift mask according to claim 4, wherein the selective etching for the light shielding film which is to be carried out is of a dry type.

12. A method of manufacturing a template to be a mother plate in use of a pattern transfer method or nano-imprinting method by using a mask blank, comprising the steps of:
forming a thin film on a base layer on which a three-dimensional pattern to be transferred is formed;
forming a resist layer on the thin film;
forming a resist pattern by the resist layer of the mask blank;
etching the thin film through the resist pattern functioning as a first mask, whereby a thin film pattern is formed;
etching the base layer through the thin film pattern functioning as a second mask, whereby the three-dimensional pattern is etched on the base layer;
removing the resist layer;
forming an alignment mark forming film on the base layer, and
selectively etching the alignment mark forming film by using a resist film with a pattern for an alignment mark portion being formed, whereby the phase shift pattern is exposed while leaving a desirable alignment mark in any part of outer peripheral portion other than a portion of the three-dimensional pattern being formed.
